(19) United States
(12) Patent Application Publication
(10) Pub. No.: US 2004/0072385 A1
(43) Pub. Date: Apr. 15, 2004

(54) Chip alignment and placement apparatus for integrated circuit, mems, photonic or other devices

(76) Inventors: Donald G. Bauer, Laurel, MD (US); Michelle D. Bryden, Ellicott City, MD (US); Richard A. Collins, Ellicott City, MD (US); Richard H. Spedden, Clarksville, MD (US)

Correspondence Address: Donald L. Bowman, Westvaco Corporation, 11101 Johns Hopkins Road, Laurel, MD, 20723, US

(21) Appl. No.: 10/269,326

(22) Filed: Oct. 15, 2002

(51) Int. Cl. H01L 21/00; H01L 21/301; H01L 21/46; H01L 21/78

(52) U.S. Cl. 438/68; 438/460

(57) ABSTRACT

Devices for manipulating, receiving and dispensing diced semiconductor materials, in which the semiconductor material is diced to provide partially connected dice in linear aggregations.

### CROSS RELATED APPLICATIONS

This application claims priority of U.S. application Ser. No. 10/212, 857, filed Aug. 6, 2002 and U.S. Provisional Application No. 60/328,504, filed Oct. 11, 2001. The disclosures of each application are herein incorporated by reference.

### FIELD OF THE INVENTION

This invention relates to efficient methods and devices for handling small semiconductor chip devices having an average width of approximately 1 mm or less. The method provides for more precise and efficient placement of integrated circuit devices on a substrate during the manufacture of radio frequency identification (RFID) and other electronics systems.

### BACKGROUND OF THE INVENTION

Several well-known processes including photolithography and etching, among other means, have been used to fabricate integrated circuit (IC) devices. By such means, small IC devices, hereinafter referred to as “chips,” may be produced from a single wafer that has been sliced from an ingot of a suitable semiconductor material. The semiconductor material is typically silicon or a silicon alloy such as silicon-germanium. In such processes, after a silicon ingot has been produced, for example, it is sliced into wafers, which are each polished on either side. One face, typically the top face, of each wafer is then processed using one of several known semiconductor fabrication methods. Next, to facilitate handling of the wafer, this top face is adhered to a support, for example an adhesive film, before the wafer is thinned from the bottom surface by grinding or other known methods to a thickness of less than about 10 mils. Another adhesive backing film layer, for example a vinyl film, is then affixed to the ground bottom surface, after which the top surface support material is removed and the wafer is then cut or scored. The wafer is then separated into individual devices (“diced”) by sawing or etching, according to a rectilinear grid pattern on the wafer surface, to form individual chips, each of which is adhered on one side to the backing film layer, and maintained in spatial relationship to each other by means of their common attachment to this film. For RFID applications, the resulting chips are usually quite small in size, on the order of about 1 mm or less. Because of their diminutive size, orderly manipulation and placement of the devices after they are separated is difficult. The presence of the adhesive backing film maintains orderly positioning of the chips, and also allows ease of transport and manipulation during subsequent processing operations.

The discoid configuration of chips bound together by the adhesive film is then placed in an apparatus that removes and places the individual chips onto a final support substrate for forming the desired semiconductor device. Alternatively, the chips may be transferred from the wafer-film to an intermediate adhesive carrier tape from which they are then removed and placed on the ultimate substrate in preparation for building a semiconductor device. This “pick and place” method is usually accomplished by apparatus that use robotic arms to separate and remove each individual chip from the diced wafer and adhere it onto the desired substrate. In this regard, the final placement of the chip must be precise to allow it to be properly located for subsequent connection to circuitry on the substrate. This method of removing and placing individual chips is slow, because the chips are very small and fragile, and thus require careful handling. This difficulty in handling and the resulting processing inefficiency is addressed by the various embodiments of the invention described herein.

### SUMMARY OF THE INVENTION

The invention comprises a means for efficient processing of semiconductor chips that minimizes the well-recognized handling difficulties inherent to conventional pick-and-place methodology. The method provides and maintains a linear alignment of chips from the point of formation to the point of placement on the end-use substrate. A desirable feature of the invention is that the chips are separated by the cutting step into linear aggregations positioned end-to-end as sticks, from which individual chips may be systematically separated and placed on an end-use substrate. In this regard, the manner of operation is akin to that of a stapler dispensing individual staples into the desired substrate material. The invention further encompasses apparatus for manipulating and placing the chips on the end-use substrate.

### BRIEF DESCRIPTION OF THE FIGURES

FIG. 1 is a planar representation of a circular semiconductor wafer scored with a rectilinear grid pattern to delineate linear chip aggregations.

FIG. 2 is a planar representation of the semiconductor wafer of FIG. 1, showing the removal of one or more linear chip aggregations.

FIG. 2A is a transverse sectional representation of a chip that may be dispensed according to the invention.

FIG. 2B is a transverse sectional representation of a linear chip aggregation in which the individual chips are connected by a bridge of semiconductor material and an adhesive tape layer.

FIG. 2C is a transverse sectional representation of a linear chip aggregation in which the individual chips are connected by a bridge of semiconductor material without the adhesive tape layer.

FIG. 3 is an isometric view of flat magazine staplers for dispensing semiconductor chips onto substrates of varying orientation.

FIG. 3A is an isometric view of flat magazine staplers for dispensing semiconductor chips onto substrates of varying orientation.

FIG. 4 shows an alternative embodiment of a stapler apparatus comprised of multiple flat magazine staplers arranged in tandem.

FIG. 5a is an exploded isometric view of a rotary magazine stapler apparatus for receiving, transporting and dispensing linear chip aggregations onto a substrate.

FIGS. 5b is a transverse section of the outer sleeve, optional inner sleeve and cylinder components of various rotary magazines according to the invention.

FIGS. 5c is a transverse section of the outer sleeve, optional inner sleeve and cylinder components of various rotary magazines according to the invention.

FIGS. 5d is a transverse section of the outer sleeve, optional inner sleeve and cylinder components of various rotary magazines according to the invention.

FIGS. 5e is a transverse section of the outer sleeve, optional inner sleeve and cylinder components of various rotary magazines according to the invention.

FIG. 6A is an exploded isometric view of a rotary magazine equipped with a grooved inner sleeve and a slotted outer sleeve for receiving and dispensing the linear chip aggregations.

FIG. 6B provides an exploded isometric view of a rotary magazine having a grooved inner sleeve equipped with vacuum ports for accommodating linear chip aggregations and an outer sleeve with slots for insertion and release of linear chip aggregations.

FIG. 7 is an isometric view of a dispensing device attached to a rotary magazine.

FIG. 8A is a planar representation of a dispensing device for use with either a flat or rotary magazine in the process of the invention.

FIGS. 8B is a transverse view of a vacuum device, which is an optional element of the dispensing device.

FIGS. 8C is a transverse view of a vacuum device, which is an optional element of the dispensing device.

FIG. 8D is a planar representation of another dispensing device incorporating a shutter mechanism.

FIGS. 8E through 8P are transverse views showing the operation of this dispensing device.

FIG. 9 is a schematic outlining a process of dispensing individual chips or other semiconductor devices according to the process of the invention.

FIG. 10 is a planar view of a dispensing device incorporating a tape mechanism.

FIG. 11 is an isometric view of the tape dispensing mechanism.

FIG. 12 is a transverse view of the tape in relation to a chip that will be attached to the tape.

FIG. 13 is an isometric view of a tape interposer, with an attached chip, being attached to the poles of an antenna.

### DETAILED DESCRIPTION OF THE INVENTION

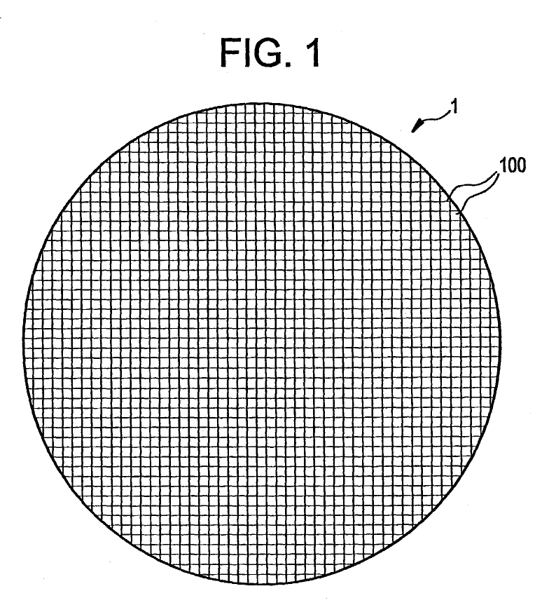

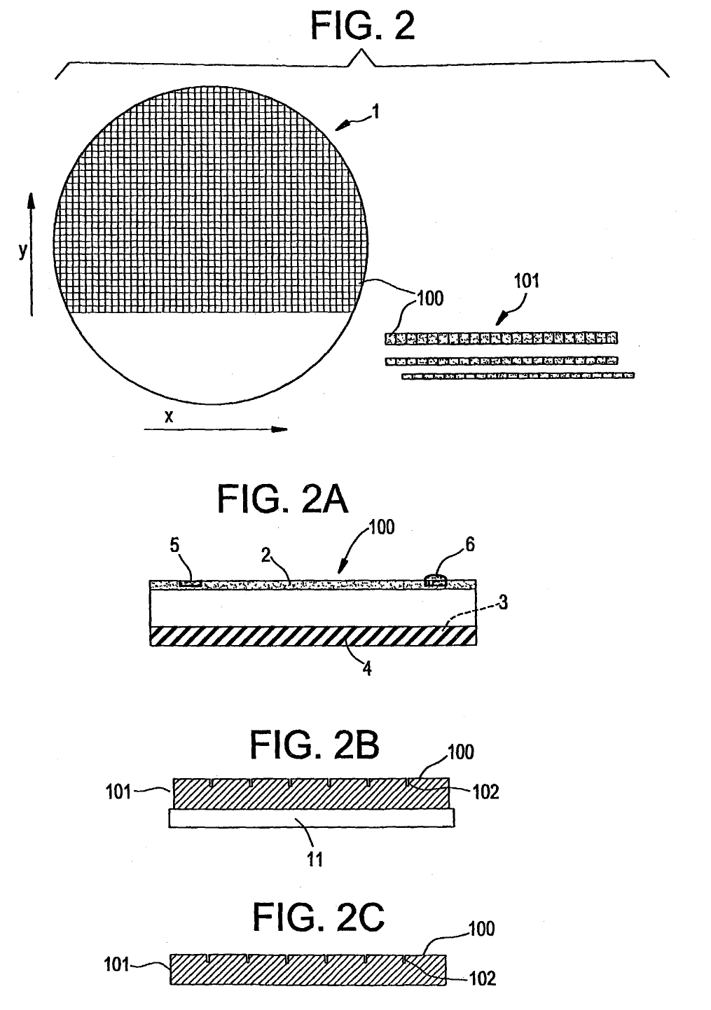

According to the accompanying figures, a standard semiconductor wafer 1 as shown in FIG. 1 may be broken by cutting, sawing or other dicing methods into linear chip aggregations 101, each composed of individual semiconductor chips 100. According to the invention, the wafer 1 is sawed to achieve partial perforation along one axis and complete penetration along the perpendicular axis. In this manner, multiple linear chip aggregations 101 may be formed from the wafer 1, as shown in FIG. 2. Typically, the linear chip aggregations 101 may comprise up to about 150 individual chips aligned end to end in stick fashion, each chip 100 being approximately 1 mm or less in width. The shape, whether square or rectangular, and size of the individual chips may vary depending on the cutting dimensions applied to the wafer 1. In a preferred embodiment, however, the chips 100 are formed according to approximately square dimensions.

As shown in FIG. 2A, each individual chip 100 deposited using the process of the present invention typically includes micro-circuitry 2 deposited by conventional means (e.g. photolithography, vapor deposition or other known means) on its surface. Chip 100 may further have deposited thereon one or more electrical contacts 5 and, optionally, one or more bumped contacts 6 for improving electrical receptivity on the top face of the chip. Preferably, the bottom face 3 of the wafer 1 is thinned before sawing by grinding or other conventional means, after which an adhesive carrier film 4 is applied to the ground surface to maintain alignment and proximity of the chips on the wafer during dicing, transport and in subsequent applications.

FIG. 2B is a cross section of a linear chip aggregation 101 in which the dicing is achieved by partial cutting that leaves semiconductor bridges 102 between individual chips 100. Furthermore, an adhesive film 11 is adhered to the bottom surface of the linear chip aggregation 101. Alternatively, the linear chip aggregation 101 may be formed with semiconductor bridges 102 in the absence of a supporting adhesive layer, as shown in FIG. 2C.

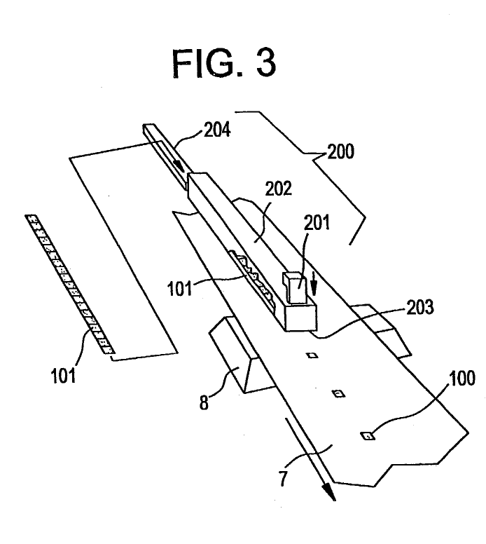

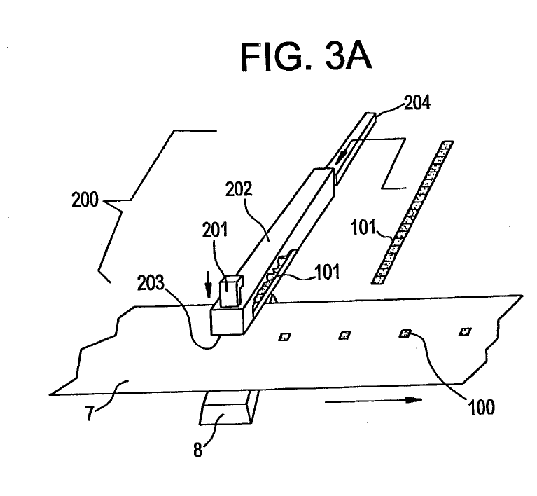

FIG. 3 provides an isometric external view of a flat magazine stapler apparatus 200 for receiving linear chip aggregations 101. Stapler 200 is comprised of a flat magazine 202, a dispensing opening 203, a first tamping means 204 for moving the one or more linear chip aggregations through the flat magazine 202, and a second tamping means 201. The stapler 200 is positioned in fixed or movable relationship to a substrate 7 and aligned at the shortest possible distance from the surface of the substrate 7 to allow deposition of individual chips 100 from the dispensing opening 203. The substrate 7 is preferably a flexible substrate made of a material such as paper, paperboard, plastic, or laminates of various flexible conductive or non-conductive materials. It is supported or moved in parallel or transverse orientation to the dispensing opening 203, for example over one or more supports 8. According to the embodiment of FIG. 3, as the substrate 7 is moved over the support 8, individual chips 100 are deposited through the dispensing opening 203 onto substrate 7. In this regard, as the substrate 7 is advanced, a linear chip aggregation 101 is advanced through the flat magazine 202 a sufficient distance to expose and align the outer edge of the chip aggregation 101 with a second tamping means 201 and the surface of the substrate 7. The exposed chip 100 is then severed by application of perpendicular force from the tamping means 201. Optionally, the edge of the flat magazine 202 directly beneath the second tamping means 201 may be equipped with a cutting edge (not shown) to sever the chip 100 in concert with the force applied by the tamping means 201. The precise placement of chip 100 is facilitated by maintaining close proximity of the dispensing opening 203 with the surface of the substrate 7, and by eliminating flipping or random movement of the chip 100 during its severance and deposition. Generally, random movement and flipping may be minimized by pre-applying an adhesive coating or film on the surface of substrate, or, alternatively, by incorporating a releasable vacuum source into the tamping means 201 to ensure controlled delivery onto the target surface. As shown in FIG. 3A, the substrate 7 may be oriented to move in a direction perpendicular, or at any other angle, to the dispensing orientation of the stapler 200. The substrate 7 may be momentarily halted during chip placement, or the stapler 200 and support 8 may be reciprocated along the direction of the moving substrate 7 so that the substrate 7, stapler 200 and support 8 are moving at the same speed at the time of placement.

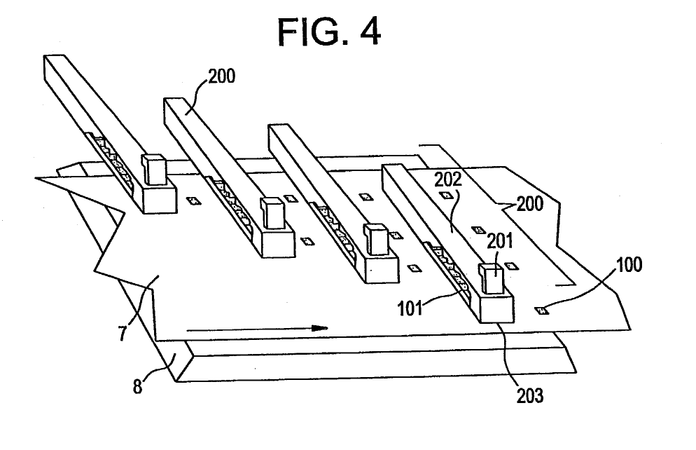

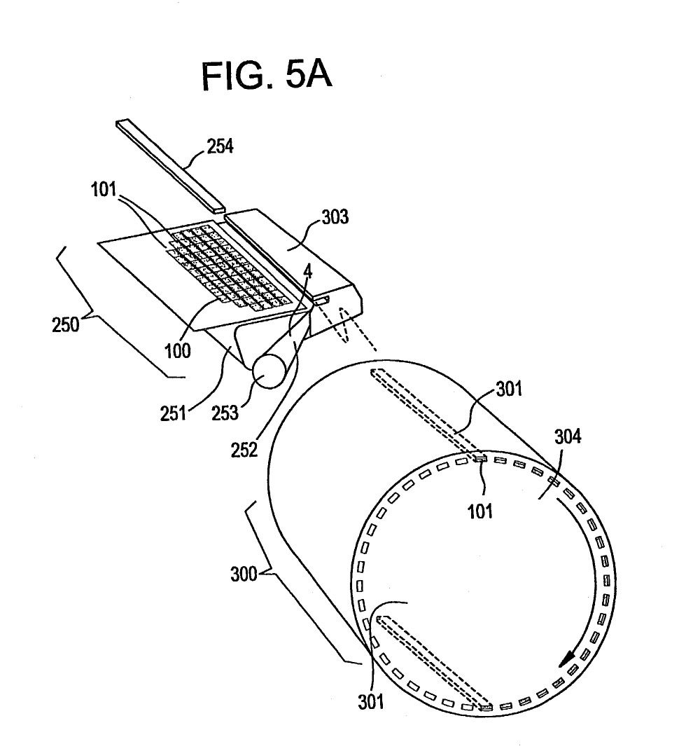

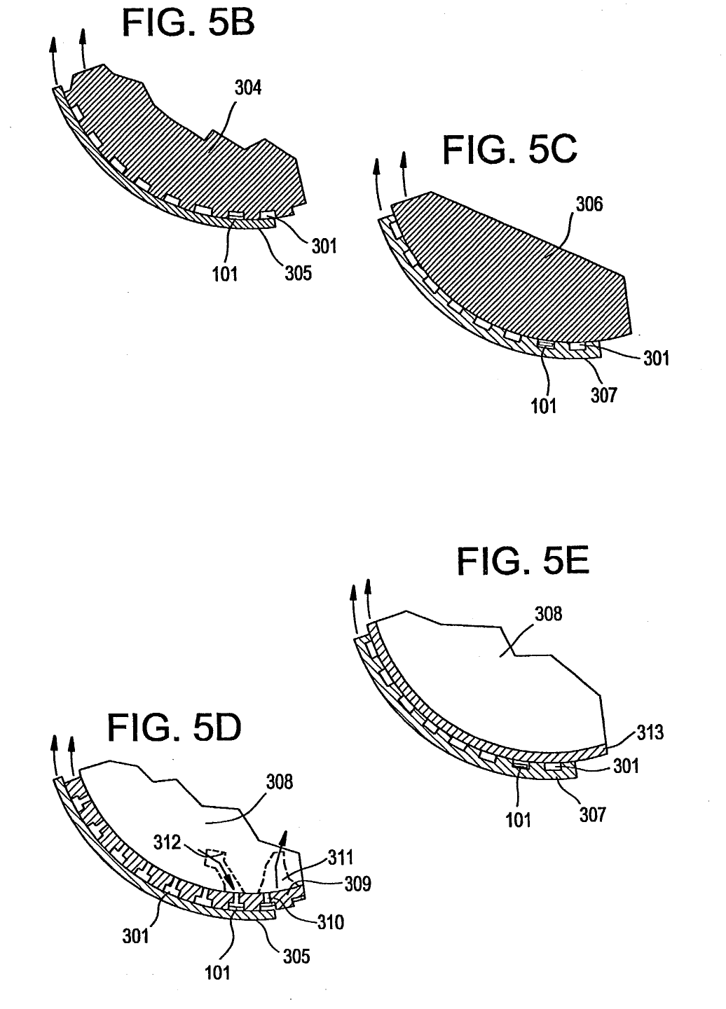

Multiple flat magazine staplers may be arranged in tandem to provide synchronized and efficient placement of individual die, as shown in FIG. 4. The linear chip alignments are individually separated from the wafer and transferred to the magazine. The loading device used at this step in the process may be used in cooperation with the aforementioned flat magazine or with other magazines, such as the rotary magazines described herein. One such loading device 250 is exemplified in the embodiment of FIG. 5A, which further depicts a rotary magazine 300. Loading device 250 comprises an angled support 251 having an edge 252 of narrowed dimension in relation to the rest of support 251. Backing adhesive film 4 is wound around a rotating means 253, which, by periodically turning to pre-set stops, advances linear chip aggregation 101 into the receiving slot 303. Linear chip aggregations 101 are mounted on support 251 and then loaded into individual chambers 301 in the magazine 300. It should be understood that as an alternative, the wafer may be previously separated into linear aggregations, which can then be serially loaded directly into receiving slot 303. Linear chip aggregation 101 is moved over support 251, passed into receiving slot 303, and is moved into chamber 301 by lateral pressure applied by tamping means 254. An example of a suitable loading device that may be used in the process of this invention is described in U.S. Pat. No. 4,590,667, herein incorporated by reference. The apparatus described therein provides separation of individual rows of completely separated semiconductor dice to allow vacuum pickup and placement of individual die. The loading device of the present invention is modified to permit simultaneous pickup and transfer of multiple dice in the form of the linear chip alignments previously described herein. The loading device may be used in cooperation with, or as an integrally formed part of any of the magazines described herein.

To protect the electronic circuitry on the face of the chips 100, the multiple chambers 301 may be lined with or coated with low-friction materials such as Teflon®. Such low-friction materials may be used in any other parts of the invention where the linear chip aggregations 101 may move in sliding motion along confining surfaces. Rotary magazine 300, as shown in FIG. 5A, includes a core cylinder 304 equipped with conventional turning means (not shown) and multiple chambers 301 around the periphery of cylinder 304. Each chamber 301 is sized to accommodate at least one linear chip aggregation 101. The rotation of the cylinder 304 is preferably synchronized to align an empty chamber 301 with receiving slot 303 as tamping force is applied from tamping means 254, thus facilitating transfer of the linear chip aggregation 101 into the chamber 301, after which the cylinder 304 is again rotated and the process repeated. The rotary magazine 300 can thus be loaded offline in this manner and later employed in a latter process, or it may be disposed for continuous loading by the process described above and off-loaded in an inline process.

FIGS. 5B, 5C, 5D and 5E are transverse sections of various configurations of the chambers 301 in relation to the core cylinder of rotary magazine 300. According to FIG. 5B, smooth outer sleeve 305 is attached to and cooperates in rotation with a toothed cylinder 304, which has indentations on the outer surface thereof that form chambers 301. Alternatively, according to FIG. 5C, a smooth core cylinder 306 may be disposed in proximate, rotational relation to a grooved outer sleeve 307, which includes indentations on the inner surface thereof that form chambers 301. FIG. 5D shows a smooth outer sleeve 305 rotationally operable in relation to a stationary, non-rotating core cylinder 308. A toothed inner sleeve 309 with grooves forming chambers 301 is disposed between outer sleeve 305 and the stationary core cylinder 308. In operation, inner sleeve 309 and outer sleeve 305 are rotated. In an optional modification, outer sleeve 305 is kept stationary. Inner sleeve 309 includes ports 310 through which vacuum may be applied through vacuum passages 311 within core cylinder 308 to hold linear chip aggregations 101 in chambers 301. Vacuum pressure is applied to ports 310 during pickup and transport only. Linear chip aggregation 101 is released after chamber 301 has rotated to the desired position, at which time contact between ports 310 and vacuum passages 311 is lost and, optionally, contact with pressure passages 312 is engaged. Application of positive pressure through the passages 312 releases the hold on the linear chip aggregation 101 and optionally, may be used to help move the linear chip aggregation 101 from the chamber 301. The rotary magazine of FIG. 5E is composed of a grooved outer sleeve 307, and a smooth inner sleeve 313, which both rotate around a stationary core cylinder 308. In a further embodiment, the vacuum and pressure system of FIG. 5D can also be implemented in the magazine of FIG. 5E. It should be understood that with the embodiments shown in FIGS. 5B-5E, only the toothed or grooved member must rotate. Rotation of other members is optional, although it may be preferred in some cases to minimize friction on the linear chip aggregation 101. However, in FIG. 5D, the inner core cylinder must be non-rotating in order to preserve the sequencing of the vacuum and pressure ports 310.

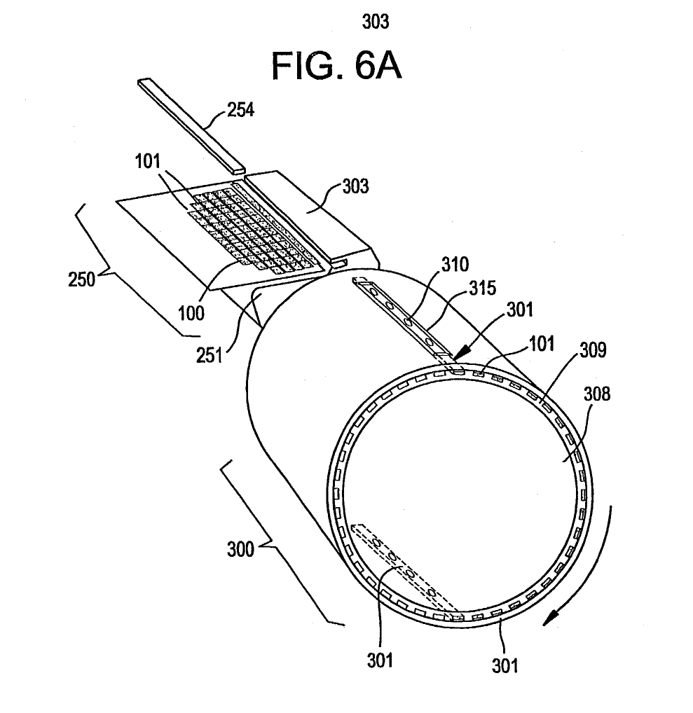

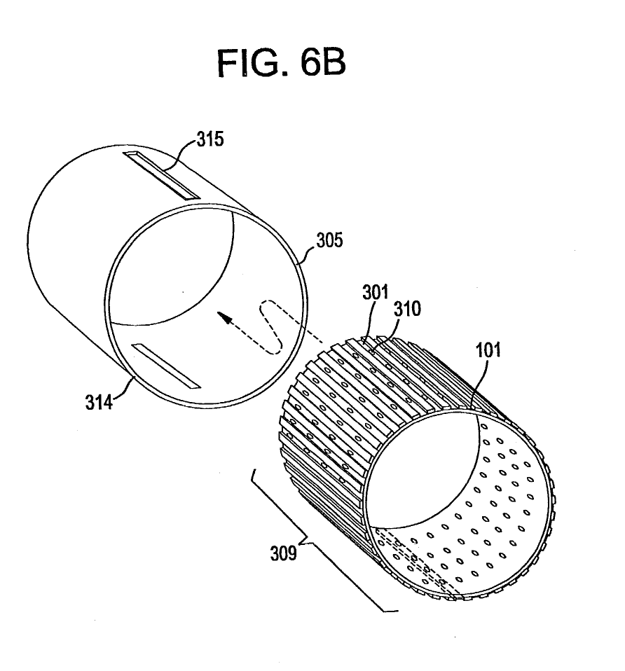

In yet another embodiment similar to that shown in FIG. 5D, the chambers 301 are located on the external surface of an inner sleeve 309, as shown in FIG. 6A. Sleeve 309 comprises a series of vacuum ports 310, which are used to selectively attract and retain linear chip aggregations 301. Outer sleeve 314 is stationary, as is core cylinder 308. Rotating inner sleeve 309 further includes grooves forming chambers 301. Outer sleeve 314 is fitted with a slot 315 for insertion, and optionally removal of linear chip aggregations 101. Chambers 301 are connected to core cylinder 308 through ports 310 that are in communication with vacuum passages 311 and pressure passages 312, as shown in FIG. 5D. FIG. 6B is an exploded isometric view of a toothed inner sleeve 309 relative to outer sleeve 314.

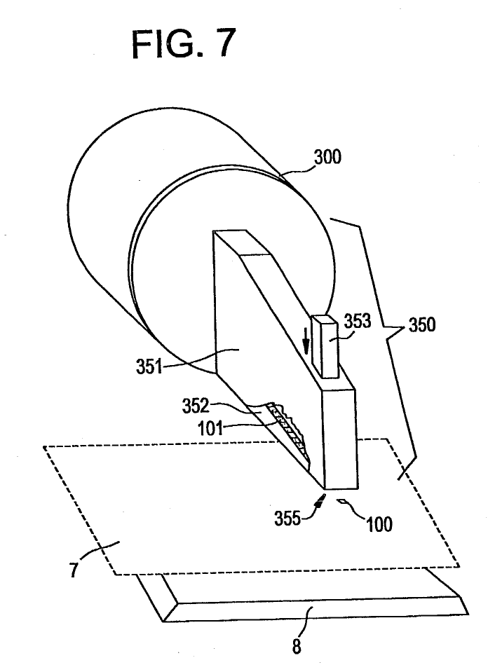

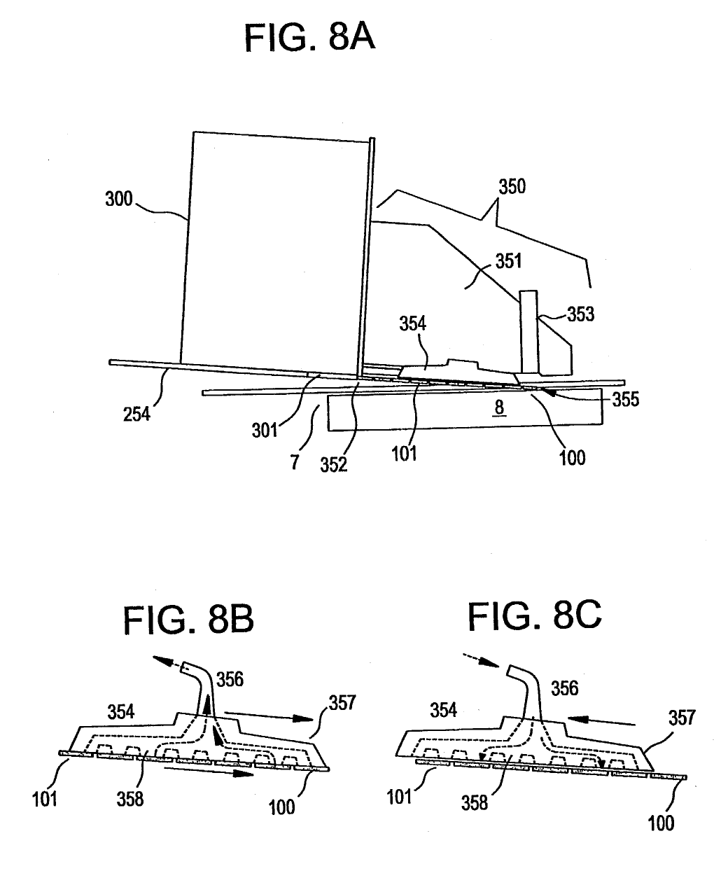

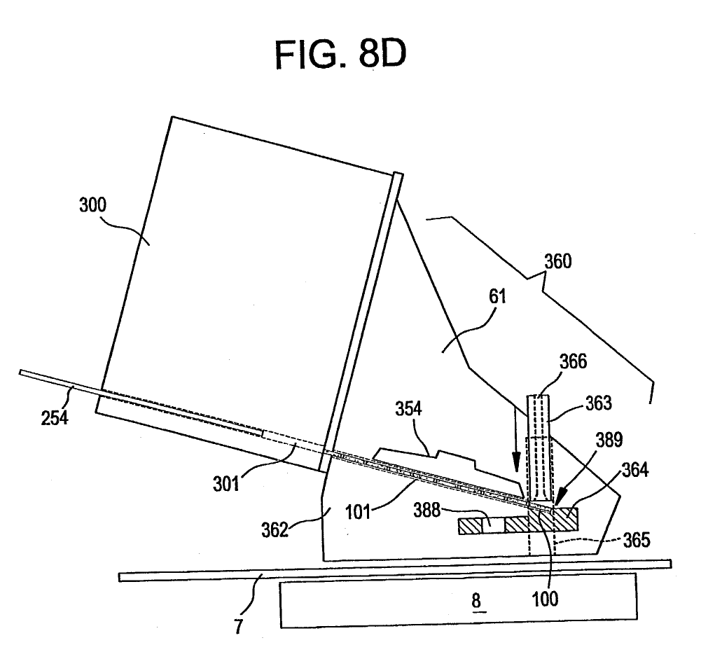

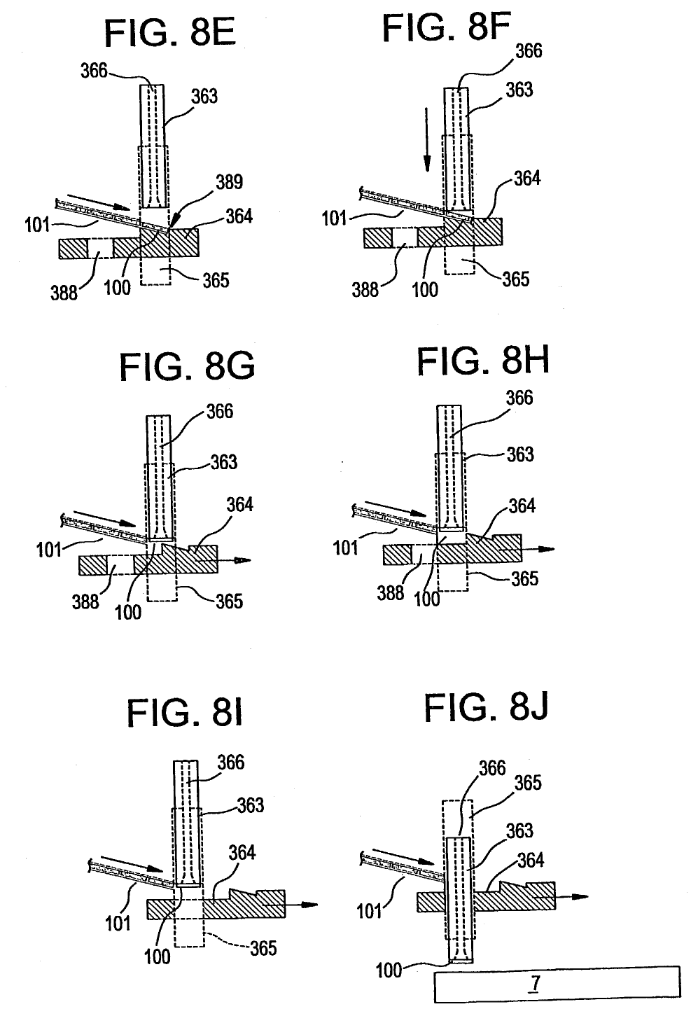

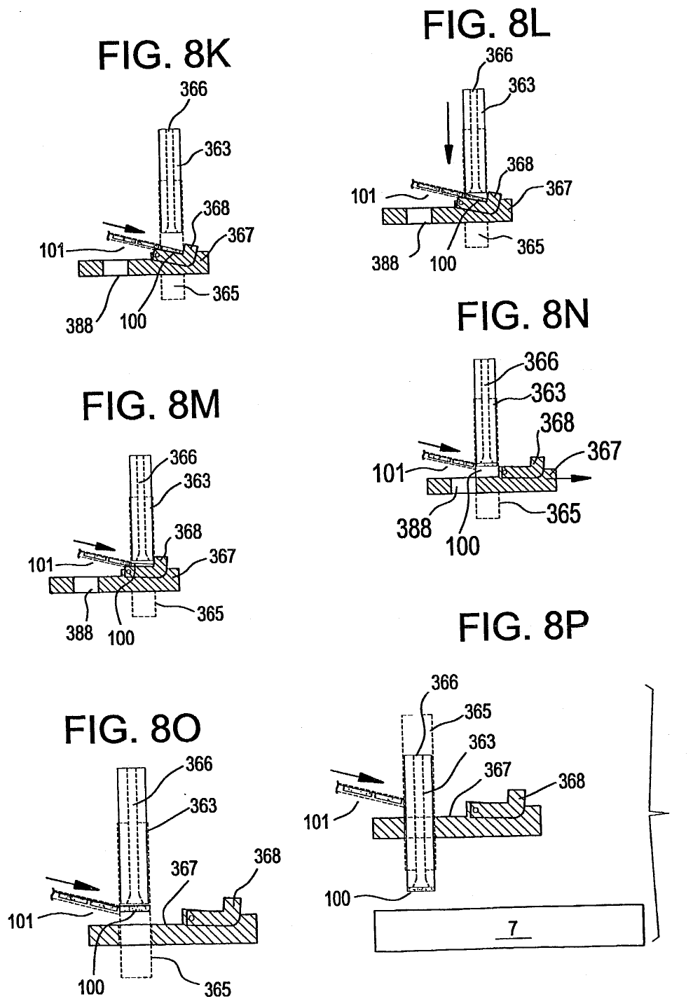

The flat or rotary magazine may be connected to a dispensing device 350, as shown in FIGS. 7 and 8A, which separates individual die from each linear chip aggregation and places them according to the desired subsequent processing step. Dispensing device 350 comprises a housing 351, which sheathes a transfer support 352 for the moving linear chip aggregation 101, and a tamping means 353, which applies downward pressure to the top surface of chip aggregation 101 to separate it and move it through a dispensing opening 355 onto the desired substrate 7. Device 350 additionally includes a vacuum device 354, which, in cooperation with transfer support 352, attaches and releases chip aggregation 101 at a series of pre-determined positions as it is moved through device 350. In this respect, to move the linear chip aggregation 101 forward, vacuum device 354 exerts negative pressure directly over the transfer support 352, generating a suction action that attachably removes and suspends chip aggregation 101. Device 354 is then moved forward one position such that one die is extended directly beneath tamping means 353, at which point the negative pressure is decreased and the chip aggregation 101 is thereby released. The tamping means 353 is then lowered over the single die 100 and pressure applied to sever it from the chip aggregation 101,after which it is released through dispensing opening 355. After release of the die 100, vacuum device 354 is moved backward one or more positions, as necessary, to reload and reposition the chip aggregation 101 for subsequent dispensing. The positioning of device 354 may be determined by the use of sensors or other conventional detecting devices. Device 350 may be used in conjunction with a support 8, as previously described, which provides additional support to a substrate 7, as it is moved in relation to the dispensing opening 355. As linear chip aggregation 101 is used up, additional linear chip aggregations are loaded into dispensing device 350 from rotary magazine 300 by the action of tamping device 254. It should be noted that tamping device 254 may conform to different shapes and dimensions in the various embodiments of the invention.

FIGS. 8B and 8C show operation of the vacuum device 354, which is composed of an inlet/outlet port 356, housing 357, and ports 358. Ports 358 are alternately evacuated to produce a vacuum that attaches linear chip aggregation 101, or are pressurized with a suitable pressurizing medium to detach the linear chip aggregation 101. FIG. 8D reflects an alternate dispensing device 360 which comprises a housing 361, a transfer support 362, a tamping means 363, a shutter device 364, and a dispensing opening 365. The shutter 364 prevents the last few chips 100 in a linear chip aggregation 101 from falling through dispensing opening 365 prematurely. The transfer support 362 is thick enough in cross section to permit inclusion of devices as wheel, belts, etc (not shown) internally for helping to move the linear chip aggregation 101 through the dispensing device. In particular the thicker transfer support 362 will allow the use of a vacuum device 354 above the linear chip aggregation (as shown), or below the linear chip aggregation (not shown), or as a pair of similar and corresponding devices located above and below the linear chip aggregation (not shown).

As shown in FIG. 8E, the linear chip aggregation 101 moves forward at the start of a processing cycle, until the forward edge of the first chip 100 comes into contact with a stop edge 389 on shutter device 364. FIG. 8F shows how the tamping means 363 is lowered with light pressure, typically less than the amount that would break the chip 100 loose from linear chip aggregation 101, until tamping means 363 comes in contact with chip 100. Meanwhile a vacuum may be pulled through passage 366 within the tamping means 363, to hold the chip 100 once it is broken free of linear chip aggregation 101.

As shown in FIG. 8G, the shutter device 364 is moved sideways so that its surface supporting chip 100 lifts the chip out of line with linear chip aggregation 101, until at some point the chip 100 will break free from linear chip aggregation 101. The top surface of the shutter device 364 may be coated with an appropriate material such as Teflon® or other substance to prevent scratching the electronics on chip 100. FIG. 8H shows how the shutter device 364 continues to move until it is completely clear of the separated chip 100, which is now held on the end of tamping means 363, by a vacuum applied through passage 366. At the same time an opening 388 in the shutter device 364 is moved toward the opening 365 in the dispensing device.

As shown in FIG. 8I, the shutter device 364 is further moved until the opening 388 in the shutter device 364 lines up with the opening 365 in the dispensing device. Finally FIG. 8J shows how the tamping means 363 lowers the chip 100 down through openings 388 and 365 to place the chip 100 onto the substrate 7. Once the chip 100 is in contact with the substrate, it may be released by removing the vacuum in passage 366. FIGS. 8K through 8P show the operation of another embodiment of a dispensing device including a rotating member. The rotating member may be an element of a shutter, for example, or the entire shutter itself may be capable of rotation. In the embodiment shown, shutter 367 is equipped with a breaking arm 368. Instead of the shutter 367 sliding sideways to break the chip 100 free from linear chip aggregation 101, the breaking arm 368 pivots upwards to break the chip 100 free from linear chip aggregation 101. This may result in less frictional force on the chip surface.

As shown in FIG. 8K, the linear chip aggregation 101 moves forward at the start of a cycle, until the forward edge of the first chip 100 is stopped by contact with breaking arm 368 on shutter device 367. FIG. 8L shows how the tamping means 363 is lowered with light pressure, typically less than the amount that would break the chip 100 loose from linear chip aggregation 101, until tamping means 363 comes in contact with chip 100. Meanwhile a vacuum may be pulled through passage 366 within the tamping means 363, to hold the chip 100 once it is broken free of linear chip aggregation 101.

As shown in FIG. 8M, the breaking arm 368 is rotated or tilted upwards so that its surface supporting chip 100 lifts the chip out of line with linear chip aggregation 101, until at some point the chip 100 will break free from linear chip aggregation 101. The top surface of the breaking arm 368 may be coated with an appropriate material such as Teflon® or other substance to prevent scratching the electronics on chip 100. FIG. 8N shows how the shutter device 367 continues to move until it is completely clear of the separated chip 100, which is now held on the end of tamping means 363, by a vacuum applied through passage 366. At the same time an opening 388 in the shutter device 367 is moved toward the opening 365 in the dispensing device.

FIG. 8O shows how the shutter device 367 after it has further moved until the opening 388 in the shutter device 367 lines up with the opening 365 in the dispensing device. Finally, FIG. 8P shows how the tamping means 363 lowers the chip 100 down through openings 388 and 365 to place the chip 100 onto the substrate 7. Once the chip 100 is in contact with the substrate, it may be released by removing the vacuum in passage 366.

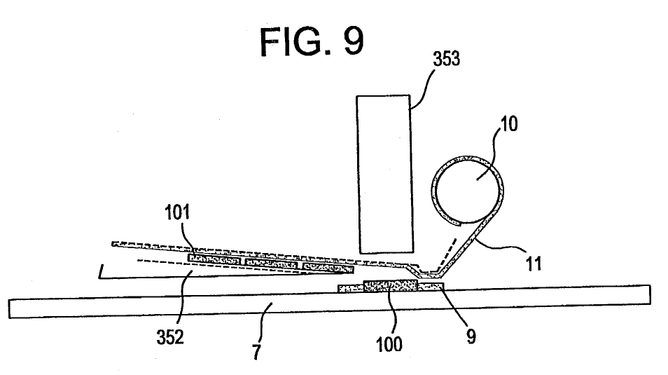

A continuous die placement process is shown in FIG. 9. By such a process, an optional carrier adhesive tape or film having one or more linear chip aggregations superimposed thereon may be moved in relation to the previously described dispensing device 350 (not shown), and single dice severed and deposited onto a substrate. As shown, linear chip aggregation 101, which is mounted top face down on an adhesive carrier film 11, is moved beneath tamping device 353. If the adhesive carrier is to be removed, it may be removed via a take-up winder 10. Use of an adhesive carrier film is not essential, however, to the practice of the invention. As shown, a receptor substrate 7 additionally comprising a localized conductive tape area 9 is positioned beneath the carrier film 11. The downward tamping action of the device 353 dislodges die 100 from the carrier 11 and pushes it downward to adhesively contact the localized adhesive area 9 on moving substrate 7. If the chip has capacitive contacts, conductive area 9 may be replaced by a non-conductive type of adhesive applied to substrate 7 before chip 100 is attached.

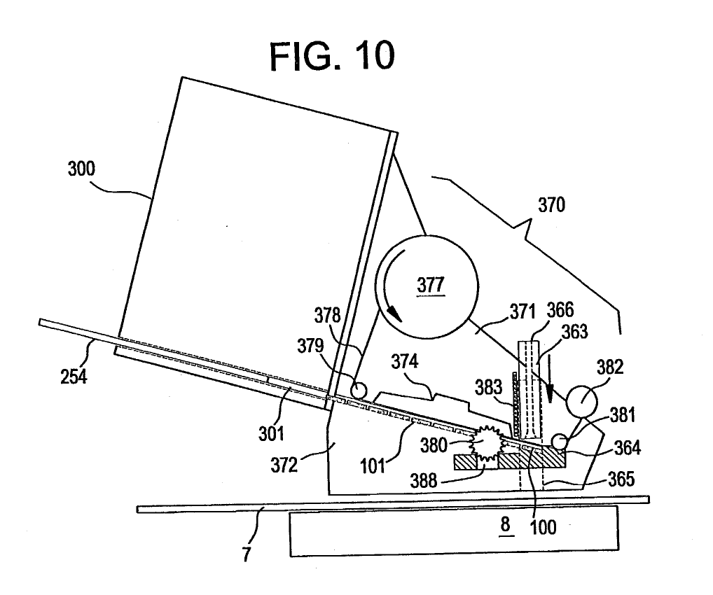

According to FIG. 10, an alternative dispensing device 370 comprises housing 371, transfer support 372, tamping means 363 with vacuum passage 366, vacuum/thermal device 374, shutter 364, and openings 365 and 388. Furthermore there is provided a supply roll 377 of a conductive tape 378. The tape 378 travels around first capstan 379, and then under the vacuum device 374 while still being over the linear chip aggregation 101, which in this embodiment is positioned with the circuitry side of the chips facing upwards. Tape 378 travels forward through the dispensing device 370, and contacts a pair of side-cutting blades 380. These blades 380 separate side strips of the tape, which continue under second capstan 381, and onto windup roll 382. It should be realized that some or all parts of the mechanism for applying the tape 378 (elements 377, 379, 381, 382) could be located below the linear chip aggregation 101, instead of above the linear chip aggregation as shown. A crosscutting blade 383 is used to cut the tape holding chip 100 to linear chip aggregation 101.

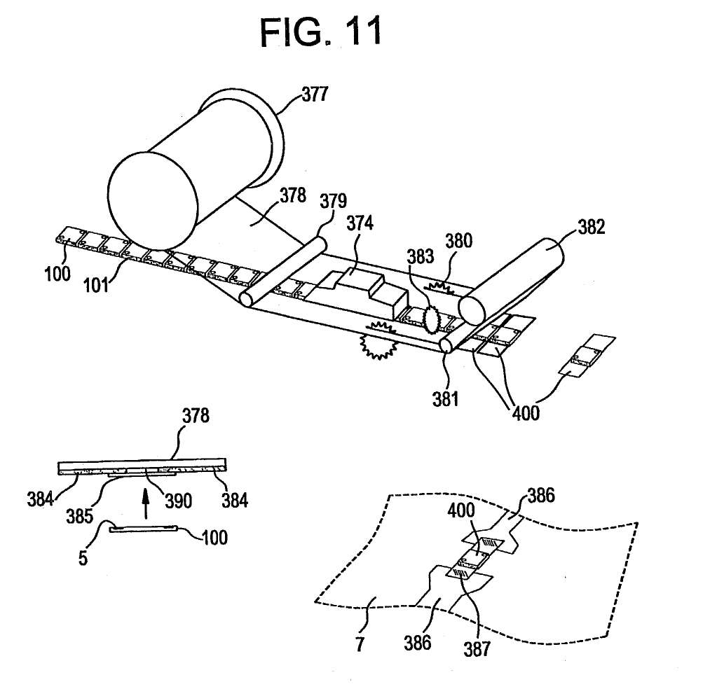

FIG. 11 shows an isometric view of the movement of the tape 378, which is provided from supply roll 377. For clarity the tape 378 is drawn as if it were transparent, however this is an optional feature. FIG. 12 shows a cross section of the tape 378, drawn in relation to a chip 100 that is shown below the tape 378. Chip 100 includes electrical contact areas 5. The tape 378 includes conductive areas 384 on each side of one face, separated by a non-conductive area 390 located approximately in the center area of the tape. Bridging the non-conductive area and wide enough to slightly overlap both conductive areas 384 is a strip 385 of anisotropic conducting film (ACF) that may be supplied from the supply roll 377, or another supply means (not shown). This material provides an anisotropic conductive center region, which completes the circuit to the chip contacts. The ACF material may be positioned off-center or over the entire surface of the tape. Alternately, the conducting material may be an anisotropic conductive paste applied to the tape 378, or to the linear chip aggregation 101, at any point before joining the tape 378 to the linear chip aggregation 101.

As the tape 378 travels through the chip dispensing mechanism 370, the first capstan 379 and second capstan 381 guide the tape 378 into a path parallel to and coming into contact with the surface of the linear chip aggregation 101. When the tape 378 and linear chip aggregation 101 have contacted, the joined pair eventually move under the vacuum/thermal device 374, which is similar to the vacuum device 354 described earlier. The vacuum/thermal device 374 helps to move the linear chip aggregation 101 through the dispensing device 370. The vacuum/thermal device is also equipped with local heating to heat the anisotropic conductive film 385 and the linear chip aggregation 101, while at the same time keeping them joined under pressure, so as to cure the anisotropic conductive film 385 and make an electrical and physical contact between the contacts 5 on chip 100 and the conducting areas 384 on the tape 378. Vacuum/thermal device 374 is preferably long enough to cover several chips, and thus, as moves forward with the linear chip aggregation 101, it remains in thermal and pressure contact long enough to cure the anisotropic conductive film 385. Accordingly, it is unnecessary to stop the substrate web 7 later for thermal/pressure curing of the anisotropic conductive film 385. Additionally, there may be fixed or movable devices (not shown) underneath the linear chip aggregation, to cooperate with vacuum/thermal device 374 and provide the pressure for curing the adhesive, and the forward motion for moving the linear chip aggregation.

As the joined tape 378 and linear chip aggregation 101 move forward through the dispensing device 370, they eventually contact a pair of side cutting blades 380, which trim any excess tape in strips away from the sides of linear chip aggregation 101. The blades are shown in FIG. 11 as serrated disks, but other types of blades or thermal or laser devices (not shown) may also be used. The excess side tape strips are then pulled under second capstan 381, and onto take-up roll 382. These excess side tape strips are optionally formed since the tape may vary in width, but where present, they provide a traction means to help pull the tape 378 and the linear chip aggregation 101 through the dispensing device 370.

Just before the linear chip aggregation 101 reaches at the dispensing opening, another blade 383 (or other cutting means) cuts crosswise through the tape 378, so that after a single chip 100 is broken loose from the linear chip aggregation 101, it will be attached to and supported by a strip of tape 378, forming tape interposer 400. As shown in FIG. 13, the tape interposer 400 carrying the chip 100 and the conductive areas 384 may then be applied to the poles 386 of an antenna stamped, etched, printed, or otherwise provided on the substrate 7. To adhere it to the substrate 7, the tape interposer 400 may have an adhesive layer provided with the tape 378, or adhesive may be applied by other means such as a coating on the substrate 7 prior to the application interposer 400. The chip 100 is connected by electrical contacts 5 through the anisotropic conductive film 385 to the conductive areas 384, and is connected to the antenna poles 386 by means such as mechanical crimping 387 to complete the antenna-chip circuit. It may be desirable to apply an overprinted varnish, another tape, or other means to protect the circuit.

The apparatus and process of the present invention therefore provide a rapid, efficient and cost-effective method of processing diced semiconductor materials. The various embodiments of the inventive concept find application in any process requiring the precise placement of small and sensitive devices that require minimal deformation or other damage, clean handling, and efficient yet precise placement on a receiving substrate. Because of such improved efficiency, products incorporating semiconductor devices such as MEMS, photonic cells, integrated circuits and other similar devices may be constructed cheaply for large-scale use. Useful applications of such cheaply produced materials include, but are not limited to, manufacture of radio frequency identification (RFID) devices such as tags for inventory control or supply chain management.

1. A method of processing semiconductor chips for integrated circuit, MEMS or photonic device manufacture comprising:
at least partly severing a wafer of semiconductor material in at least one dimension to provide at least one parting line;
completely severing the wafer in a dimension perpendicular to the at least one parting line to form one or more linear chip aggregations composed of partially joined individual chips, each linear chip aggregation being separated by one or more severed edges of the individual chips;
aligning the one or more linear chip aggregations with reception sites on a substrate;
dispensing individual chips from the one or more linear chip aggregations onto the reception sites by severing a single chip from each linear chip aggregation and contacting it with the surface of the substrate while simultaneously preserving its linear orientation and controlling its alignment on the surface of the substrate.

2. The method of claim 1, in which the step of at least partly severing the wafer is performed by sawing through less than the entire thickness of the wafer.

3. The method of claim 2 in which the semiconductor wafer is backed by an adhesive material and the step of at least partly severing the wafer does not sever the adhesive material.

4. The method of claim 1 in which the dispensing of individual chips includes extending a single chip over a reception site and perpendicularly applying pressure from a tamping means to the bottom face of the chip to sever it from the linear chip aggregation and deposit it on the reception site.

5. The method of claim 1 in which the dispensing of individual chips includes extending a single chip over a reception site and severing the single chip from the linear chip aggregation by applying force from a sliding member.

6. The method of claim 1 in which the dispensing of individual chips includes extending a single chip over a reception site and dispensing the single chip from the linear chip aggregation by applying force from a device having a rotating member.

7. The method of claim 1 in which the dispensing of individual chips includes extending a single chip over a reception site and severing the single chip from the linear chip aggregation using a shutter device.

8. The method of claim 1 in which the dispensing of individual chips includes providing within the dispensing device a tape material to assist in fastening the chip to the substrate.

9. The method of claim 8 in which the tape material comprises conductive side areas for bonding to electrically active areas of the substrate, a non-conductive area between the conductive side areas, and an anisotropic conductive region for bonding to electrically active areas of the chip.

10. The method of claim 1 wherein the method of dispensing individual chips is synchronized using a sensor to detect the position of the target.

11. A stapler apparatus for dispensing diced semiconductor materials on a substrate, comprising:
one or more chambers for receiving and holding one or more linear chip aggregations; and
a dispensing device that releases individual chips from the one or more linear chip aggregations held within said chambers onto reception sites on a substrate.

12. The stapler apparatus of claim 11 where the dispensing device further includes a shutter means.

13. The apparatus of claim 11 where the dispensing device further includes a slidable member for separating individual chips from the one or more linear chip aggregations.

14. The apparatus of claim 11 where the dispensing device further includes a rotatable member for separating individual chips from the one or more linear chip aggregations.

15. The apparatus of claim 11 further comprising one or more first tamping means for loading the linear chip aggregations into the chambers.

16. The apparatus of claim 11 further comprising one or more second tamping means for dispensing chips from the dispensing device.

17. A rotary magazine for receiving and dispensing linear aggregations of diced semiconductor chips comprising at least one sleeve surrounding a core cylinder; and a series of chambers on the interior or exterior of the at least one sleeve, each chamber accommodating one or a series of linear aggregations of semiconductor chips therein.

18. The rotary magazine of claim 17 further including one or more ports for vacuum or pressure application to the chambers.
